(19) United States
(12) Patent Application Publication
(10) Pub. No.: US 2024/0347106 A1
(43) Pub. Date: Oct. 17, 2024

(54) SEMICONDUCTOR DEVICE AND CALCULATING METHOD THEREOF

(71) Applicant: Winbond Electronics Corp., Taichung City (TW)

(72) Inventor: Masaru Yano, Tokyo (JP)

(73) Assignee: Winbond Electronics Corp., Taichung City (TW)

(21) Appl. No.: 18/444,730

(22) Filed: Feb. 18, 2024

(30) Foreign Application Priority Data
Apr. 12, 2023 (JP) 2023-064783

(51) Int. Cl. G11C 11/56; G11C 11/54

(52) U.S. Cl. CPC G11C 11/5642; G11C 11/54; G11C 11/5628

(57) ABSTRACT

A semiconductor device is capable of improving calculating ability and processing efficiency in AI learning and the like. A flash memory (100) includes a NAND-type or NOR-type memory cell array (110) and a calculation processing part (190). The calculation processing part (190) includes a bit line current detection part (200); a voltage holding part (210) holding a voltage corresponding to the detected current; an adding part (220) adding voltages held by the voltage holding part (210); and an A/D conversion part (230) performing A/D conversion on an addition result of the adding part (220). The calculation processing part (190) may calculate a sum of the current flowing in a bit line in a row direction and/or a column direction when the memory cell array is read.

### CROSS-REFERENCE TO RELATED APPLICATION

This application claims the priority benefit of Japanese application serial no. 2023-064783, filed on Apr. 12, 2023. The entirety of the above-mentioned patent application is hereby incorporated by reference herein and made a part of this specification.

### BACKGROUND

### Technical Field

The present disclosure relates to a semiconductor device including a NOR type or NAND type memory cell array, and in particular to a semiconductor device capable of being used as a neuromorphic device.

### Description of Related Art

As artificial intelligence (AI) hardware that is structurally analogous to synapses and neurons, crossbar arrays using variable resistance elements are being put into practical application (for example, Japanese Patent Laid-Open No. 6818116). A crossbar array contains variable resistive elements at the intersections of row lines and column lines. The variable resistive elements store different resistance values (conductance) by applying voltage or current. By writing a desired resistance value to the variable resistance element, for example, the input signal applied to the row line is weighted by the resistance value of the variable resistance element and output from the column line.

FIG. 1 is a block diagram showing the structure of a conventional synapse array device equipped with a learning function. The synapse array device 10 includes a flash memory 20 that stores learning data, a crossbar array 30 and a controller 40. The controller 40 reads the learning data from the flash memory 20, writes the read learning data into the crossbar array 30, modulates the resistance of the variable resistance element, and performs learning of the data. In addition, the controller 40 reads the data learned in the crossbar array 30 and writes the read data into the flash memory 20.

In the existing synapse array device 10, the flash memory 20 is not equipped with a data calculation function, so matrix operations required for AI learning and the like cannot be performed. Therefore, there is a problem of low data transmission efficiency, which results in time-consuming AI learning processing.

### SUMMARY

A purpose of the present disclosure is to solve existing problems by providing a semiconductor device that may improve the calculating ability or processing efficiency of AI learning and the like.

The calculating method of a semiconductor device of the present disclosure is a calculating method of a semiconductor device including a memory cell array of a NOR type or NAND type, wherein the sum of the currents flowing in the column direction of the bit lines when each row is read is calculated in the reading operation of multiple rows of the memory cell array.

Among one of the embodiments, the calculating method further calculates the sum of the currents in the column direction and the sum in the row direction of multiple bit lines. Among one of the embodiments, the calculating method calculates the sum of the currents in the matrix direction corresponding to the data stored in the memory cells of multiple rows×multiple columns. Among one of the embodiments, the calculating method includes performing analog/digital conversion (A/D) on the sum of the currents in the column direction or the sum of the currents in the matrix direction to generate multi-bit data. Among one of the embodiments, the calculating method further includes writing multiple bits of data into the memory cells of the memory cell array. Among one of the embodiments, the memory cell array includes a first storage plane and a second storage plane. In reading out the first storage plane, the sum of the currents flowing in the bit line in the matrix direction is calculated, and multiple bits of data is written into the second storage plane. Among one of the embodiments, the calculating method calculates the sum of the first currents flowing in the first group of bit lines in the column direction, and the sum of the second currents flowing in the second group of bit lines in the column direction, as well as the difference between the sum of the first currents and the sum of the second currents. Among one of the embodiments, the sum of the first currents represents a positive coefficient and the sum of the second currents represents a negative coefficient.

The semiconductor device of the present disclosure includes: a NOR type or NAND type memory cell array, including multiple row lines, multiple bit lines, and multiple memory cells; a reading part for reading out the memory cell array; a writing part for writing the memory cell array; and a calculating part for calculating the sum of the currents flowing in the column direction of the bit lines when each row is read when the reading part performs reading of multiple rows.

Among one of the embodiments, the calculating part further calculates the sum of the currents in the column direction and the sum of the currents in the row direction of multiple bit lines. Among one of the embodiments, the calculating part calculates the sum of currents in the matrix direction corresponding to the data stored in the memory cells of multiple columns×multiple rows. Among one of the embodiments, the calculating part includes an A/D conversion part that performs A/D conversion on a sum of currents in a column direction or a sum of currents in a matrix direction to generate multiple bits of data. Among one of the embodiments, the writing part writes multiple bits of data into the memory cells of the memory cell array. Among one of the embodiments, the memory cell array includes a first storage plane and a second storage plane, the calculating part calculates the sum of the currents flowing in the bit lines in the matrix direction during reading of the first storage plane, and the writing part writes multiple bits of data into the second storage plane. Among one of the embodiments, the calculating part calculates the sum of first currents flowing in the first group of bit lines in the column direction, and the sum of second currents flowing in the second group of bit lines in the column direction, as well as the difference between the sum of the first currents and the sum of the second currents.

According to the present disclosure, by providing a calculating function for calculating the sum of currents flowing in bit lines in a semiconductor device having a NOR type or NAND type memory cell array, it is possible to improve the calculating ability or processing efficiency of AI learning and the like. In this way, a semiconductor device adaptable for neuromorphic devices may be provided.

### BRIEF DESCRIPTION OF THE DRAWINGS

FIG. 1 is a block diagram showing the structure of a conventional synapse array device.

FIG. 2 is a block diagram showing the structure of a NAND flash memory according to an embodiment of the present disclosure.

FIG. 3 is a diagram showing the structure of a block of a memory cell array.

FIG. 4 is a diagram showing a structural example of a page buffer/read circuit.

FIG. 5 is a block diagram showing the structure of a calculation processing part of a flash memory of the embodiment.

FIG. 6 is a diagram showing the functional structure of the calculation processing part shown in FIG. 5.

FIG. 7 is a diagram showing the flow of matrix operations in the embodiment.

FIG. 8 is a schematic diagram illustrating matrix operations in the embodiment.

FIG. 9 is a diagram showing the flow of operations in the row direction in the embodiment.

FIG. 10 is a schematic diagram illustrating operations in the row direction in the embodiment.

FIG. 11 is a diagram showing the flow of operations in the column direction in the embodiment.

FIG. 12 is a schematic diagram illustrating operations in the column direction in the embodiment.

FIG. 13A and FIG. 13B are diagrams illustrating writing of matrix operation results in the embodiment.

FIG. 14 is a diagram showing an example of read and write operations between storage planes in the embodiment.

FIG. 15 is a diagram showing an example of applying the flash memory of the embodiment to an auto-encoder.

FIG. 16 is a block diagram showing the structure of a calculation processing part according to another embodiment of the present disclosure.

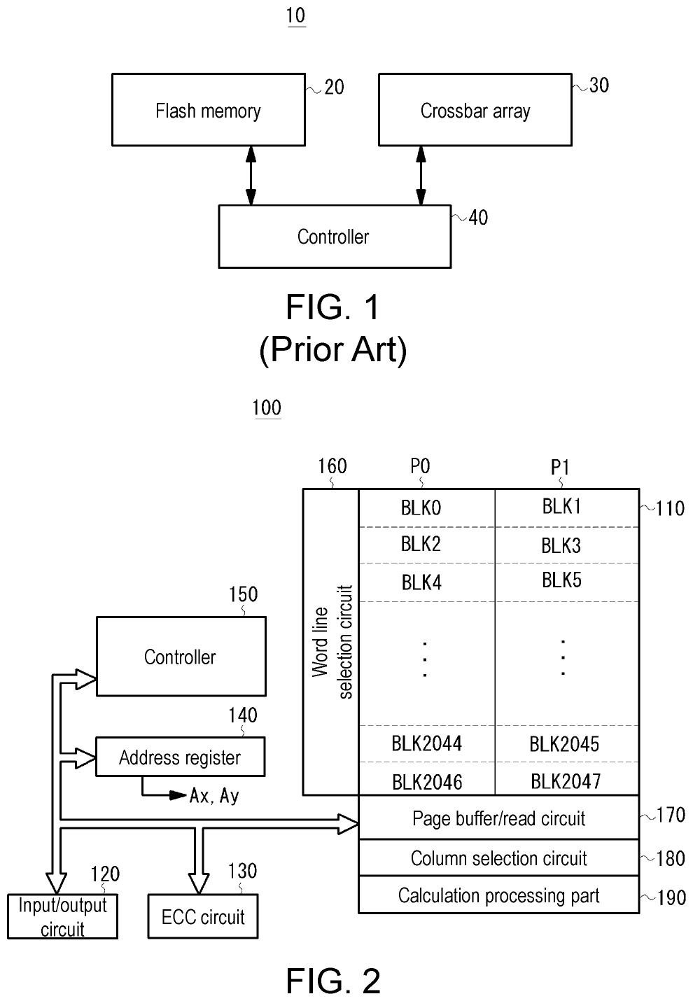

### DESCRIPTION OF THE EMBODIMENTS

The semiconductor device of the present disclosure relates to a flash memory including a NOR type or NAND type memory cell array. Among one of the embodiments, the flash memory includes the function of detecting the currents flowing in the bit lines. In the operation of reading multiple rows, the sum of the currents corresponding to the data of multiple memory cells in the column direction of the multiple bit lines may be calculated. In addition, among one of the embodiments, the flash memory includes multiple storage planes, and a matrix operation result of data read from one storage plane may be written to another storage plane. The flash memory may function as an AI memory with a learning function or a neuromorphic device by performing matrix operations on data read from a memory cell array. In the following description, a NAND flash memory having a matrix operation function is exemplified.

Next, embodiments of the present disclosure will be described with reference to the drawings. FIG. 2 is a diagram showing the structure of a NAND-type flash memory in the embodiment. The flash memory 100 includes: a NAND-type memory cell array 110 in which multiple memory cells are arranged in a matrix; an input/output circuit 120 connected to the external input/output terminal, and outputting the read data to the outside or take in the data input from the outside; an error checking and correction (ECC) circuit 130 generating the error correction code of the data to be programmed or performing error checking and correction based on the data read through the error correction code; an address register 140 receiving address data through the input/output circuit 120; a controller 150 controlling each part based on a command (instruction) received through the input/output circuit 120 or a control signal applied to the control terminal; a word line selection circuit 160 performing block selection or word line selection based on the decoding result of the row address information Ax from the address register 140; a page buffer/read circuit 170 holding data read from a selected page of the memory cell array 110, or holding data programmed into a selected page; a column selection circuit 180 performing row selection and the like based on the decoding result of the column address information Ay from the address register 140; and a calculation processing part 190 performing calculation processing on the memory cell array 110 in the row direction and/or column direction. In addition, although not shown here, the flash memory 100 includes an internal voltage generation circuit that generates the voltage (programming voltage Vpgm, pass voltage Vpass, read voltage Vread, erase voltage Vers, etc.) required for reading, programming (writing), and erasing of data. Moreover, the NAND flash memory 100 may also be equipped with a serial peripheral interface in order to realize operation compatibility with the NOR type flash memory.

Among one of the embodiments, the memory cell array 110 is not particularly limited and includes two storage planes P0 and P1. The storage plane P0 and the storage plane P1 are respectively formed in separate P wells, for example. For instance, the storage plane P0 contains 1024 even-numbered blocks (BLK0, BLK2, . . . , BLK2044, BLK2046), and the storage plane P1 contains 1024 odd-numbered blocks (BLK1, BLK3, . . . , BLK2045, BLK2047).

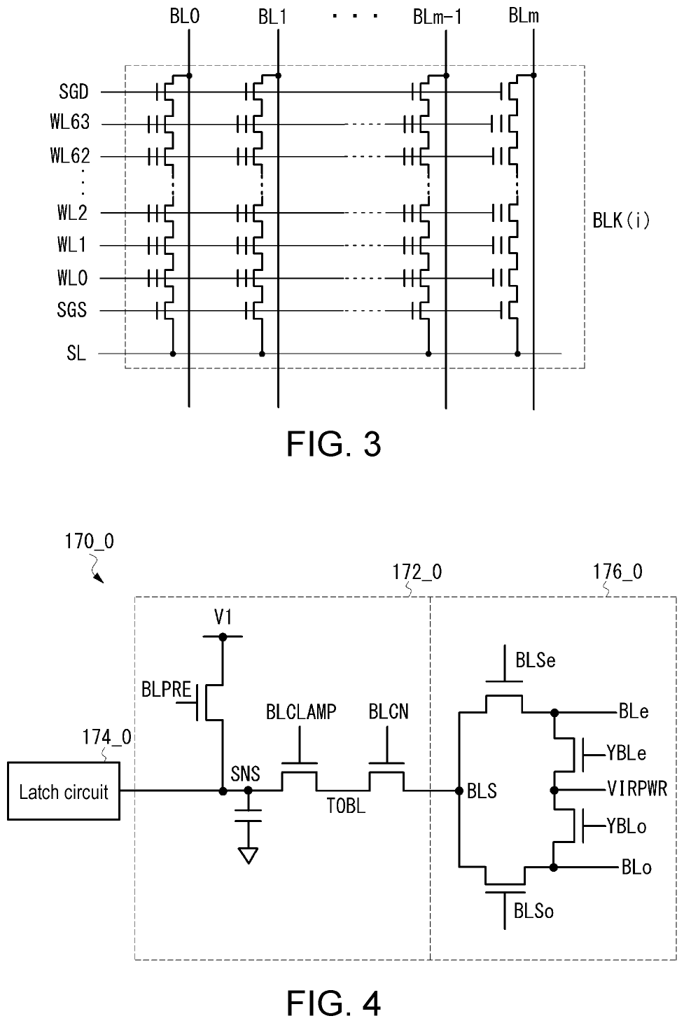

As shown in FIG. 3, multiple NAND strings are formed in one block BLK(i). An NAND string contains multiple memory cells (64 memory cells in this example), bit line side selection transistors and source line side selection transistors. The NAND string may be formed in a two-dimensional array on the surface of the substrate or in a three-dimensional array on the substrate. Furthermore, the memory cell may be a single level cell (SLC) type that stores 1 bit, or a type that stores multiple bits.

The word line selection circuit 160 selects the block of the plane P0 and/or the block of the plane P1 based on the row address information Ax, and further selects the word line of the selected block. It should be noted here that in the case where the plane P0 and the plane P1 are operated simultaneously, the word line selection circuit 160 selects the blocks of the plane P0 and the plane P1 respectively, that is, blocks of the plane P0 are selected based on the address related to the plane P0, and blocks of the plane P1 are selected based on the address related to the plane P1. Furthermore, when the plane P0 and the plane P1 are operated simultaneously, the word line selection circuit 160 outputs the selection signal SGS/selection signal SGD corresponding to the operation of the plane P0 to the bit line side selection transistor/source line side selection transistor, and outputs the selection signal SGS/selection signal SGD corresponding to the operation of the plane P1 to the bit line side selection transistor/source line side selection transistor.

The ECC circuit 130 performs error checking and correction on data to be programmed or data to be read. The ECC operation is performed by a known method such as Hamming code or Reed-Solomon code, and the input data Di of k bits or k bytes is converted into p=k+q. “q” is the error correction code or parity bit required for error checking and correction of data.

A page buffer/read circuit 170, a column selection circuit 180 and a calculation processing part 190 are prepared in the storage plane P0 and the storage plane P1 respectively. FIG. 4 shows a page buffer/read circuit and the bit line selection circuit connected thereto. The page buffer/read circuit 170_0 includes: a read circuit 172_0, which senses the data read on the bit line, or sets a voltage corresponding to the data that should be programmed; a latch circuit 174_0, which holds the sensed data or holds the data that should be programmed; and a bit line selection circuit 176_0.

The read circuit 172_0 includes a precharge transistor BLPRE connected between the voltage supply node V1 and the readout node SNS, a transistor BLCLAMP that generates a clamping voltage at the node TOBL, and a transistor BLCN connected between the node TOBL and the node BLS of the bit line selection transistor 176_0. The readout node SNS is connected to the latch circuit 174_0 through a charge transfer transistor (not shown).

The bit line selection circuit 176_0 includes a transistor BLSe for selecting the even-numbered bit line BLe, a transistor BLSo for selecting the odd-numbered bit line BLo, a transistor YBLe for connecting the virtual power supply VIRPWR to the even-numbered bit line BLe, and the transistor YBLo for connecting the virtual power supply VIRPWR to the odd-numbered bit line BLo.

Among one of the embodiments, the page buffer/read circuit 170 may include a first latch L1 capable of holding one page of data and a second latch L1 capable of transmitting data between the first latch L1 and the first latch L1. The second latch L2 of the page buffer/read circuit 170 is connected to the memory cell array 110, the ECC circuit 130, and the like through an internal bus. In addition, among one of the embodiments, the first latch L1 and the second latch L2 respectively include a first cache memory C0 and a second cache memory C1 that hold data in units of ½ page. The first cache memory C0 is configured to transfer data independently from the second cache memory C1.

In the operation of reading each storage plane, a certain positive voltage is applied to the bit line, a certain read voltage (for example, 0 V) is applied to the selected word line, and the read pass voltage Vpass is applied to the non-selected word line. The bit line side selection transistor and the source line side selection transistor are turned on through the selection signal SGD/selection signal SGS, and 0 V is applied to the common bit line. In the programming operation, a high programming voltage Vpg is applied to the selected word line, and an intermediate potential is applied to the non-selected word line, thus turning on the bit line side selection transistor and turning off the source line side selection transistor. A voltage corresponding to the programming data is applied to the bit lines. In the erase operation, 0 V is applied to the selected word line in the block, the erase voltage Vers is applied to the P well, and the data is erased in units of blocks.

The calculation processing part 190 has a function of performing matrix operations on the data read from the memory cell array 110. More specifically, in the reading of multiple rows of the memory cell array 110, the current flowing in the bit line when reading each row (page) is detected, and the sum of the detected currents is calculated, or the sum of the calculated currents is subjected to A/D conversion, and the A/D converted data is written into the memory cell array again.

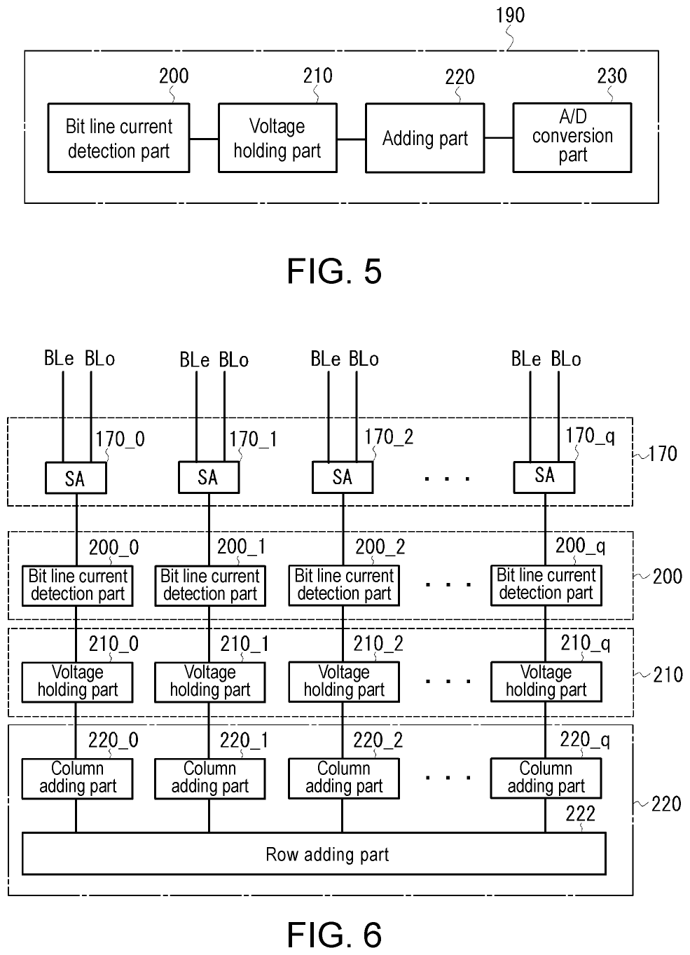

As shown in FIG. 5, the calculation processing part 190 includes and consists of a bit line current detection part 200, a voltage holding part 210, an adding part 220, and an A/D conversion part 230. When reading the selected page, when data “1” is stored in the selected memory cell, the selected memory cell is turned on, and the charges precharged to the bit line BL are discharged to the source line SL through the NAND string. On the other hand, when data “0” is stored in the selected memory cell, the selected memory cell is turned off, and the charges precharged to the bit line BL are almost not discharged to the source line SL. The bit line current detection part 200 detects the current flowing from the bit line BL to the source line SL during reading. The structure of the bit line current detection part 200 is not particularly limited. For example, the structure of the bit line current detection part 200 may be a part that connects a shunt resistor to the bit line in series and detects a voltage drop of the shunt resistor, or a current reading amplifier consisting of a combination of a shunt resistor and an operational amplifier.

FIG. 6 is a diagram showing the connection relationship between the page buffer/read circuit 170 and the calculation processing part 190. The bit line current detection part 200_0 to the bit line current detection part 200_q are respectively connected to the page buffer/read circuit 170_0 to the page buffer/read circuit 170_q, and respectively detect the currents flowing in the even-numbered bit line BLe or the odd-numbered bit line BLo selected by the bit line selection circuit. The detection results of the bit line current detection part 200_0 to the bit line current detection part 200_q are respectively held by the voltage holding part 210_0 to the voltage holding part 210_q. The structure of the voltage holding part 210 is not particularly limited, but may include, for example, a charging circuit that charges the capacitor with a charge using a diode, a switch, and a capacitor, and a reset circuit that releases the charge charged to the capacitor.

When reading multiple pages, the voltage holding part 210 may charge the capacitor for each page, and provide the charged voltage to the adding part 220 in units of pages (in this case, the capacitor is reset in units of pages), or the voltage of multiple pages may be charged to the capacitor, and the charged voltage is provided to the adding part 220 after reading out the multiple pages (in this case, the capacitor is reset after reading out the multiple pages). For example, when eight pages are read continuously, the voltage holding part 210 may output the voltage charged to the capacitor to the adding part 220 each time the reading of one page is completed, or the voltage holding part 210 may output the voltage charged to the capacitor to the adding part 220 when the reading of eight pages is completed.

The adding part 220 includes a column adding part 220_0 to a column adding part 220_q that add up the voltages in the column direction of the bit lines, and a row adding part 222 that adds up the voltages in the row direction of the plurality of bit lines. The structure of the row adding part 222 is not particularly limited. For example, the structure of the row adding part 222 may be configured using an operational amplifier that adds up a plurality of input voltages. As shown in FIG. 6, the column adding part 220_0 to the column adding part 220_q are connected to the voltage holding part 210_0 to the voltage holding part 210_q, and voltages held by the voltage holding part 210_0 to the voltage holding part 210_q are input, and these input voltages are added. The row adding part 222 inputs the voltage output from the column adding part 220_0 to the column adding part 220_q, and these input voltages are added.

The A/D conversion part 230 inputs the analog voltage output from the adding part 220, and converts the analog voltage into digital data of a predetermined plurality of bits. The digital data converted by the A/D conversion part 230 is written (programmed) again into the selected page in the selected block of the memory cell array.

The controller 150 includes, for example, a microcontroller or a state machine including read-only memory/random access memory. In this embodiment, the controller 150 controls the calculation processing part 190 during the read operation or the write operation, for example, through new instructions. Among one of the embodiments, the following control operation is performed: when the storage plane P0 or the storage plane P1 is read, the current flowing in the bit line is detected, the matrix operation of the detected current is performed, and the analog data subjected to the matrix operation is converted into digital data through the A/D conversion part 230, and the converted digital data is written to another storage plane P1 or storage plane P0.

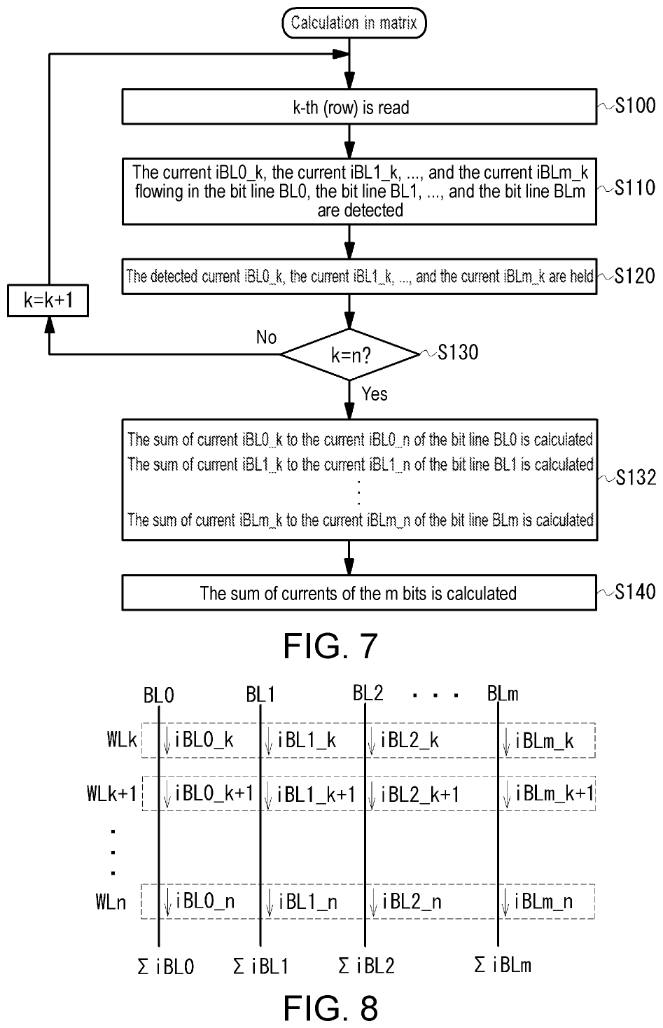

Next, the matrix operation of the flash memory 100 of this embodiment will be described. FIG. 7 is a flow showing an example of a matrix operation, and FIG. 8 is a schematic diagram for explaining the matrix operation shown in FIG. 7. The matrix operation here is performed, for example, when continuously reading the k-th page to the n-th page (multiple pages) in the selected block of the storage plane P0.

When receiving instructions and addresses for performing matrix operations from the host-side system, the controller 150 starts to continuously read multiple pages according to the instructions. When the k-th page (row) of the storage plane P0 is read (S100), the current precharged to each bit line flows to the source line according to the data stored in the selected memory cell of the selected page. If the memory cell is selected to be turned on, the charge of the bit line will be discharged to the source line. If the memory cell is selected to be turned off, the charge of the bit line will hardly change. The bit line current detection part 200 detects the current iBL0, the current iBL1, . . . , and the current iBLm flowing in the bit line BL0, the bit line BL1, . . . , and the bit line BLm (S110). Referring to FIG. 8, when word line WLk is selected, the current iBL0_k to the current iBLm_k flowing in each of bit line BL0 to the bit line BLm are detected, and the detection results are held in the voltage holding part 210 (S120).

During the period of continuously reading the k-th page to the n-th page, the currents flowing in the bit line BL0 to the bit line BLm when each page is read is detected, and the voltage corresponding to the currents is held in the voltage holding part 210 (S130). Referring to FIG. 8, when word line WLk+1 is selected, the current iBL0_k+1 to the iBLm_k+1 flowing in each of the bit line BL0 to the bit line BLm are detected, and the same detection is performed thereafter. When the word line WLn is selected, the current iBL0_n to the current iBLm_n flowing in each of the bit line BL0 to the bit line BLm are detected.

Next, the column adding part 220_0 to the column adding part 220_q calculate the sum ΣiBL0 to the sum ΣiBLm of currents of each of the bit line BL0 to the bit line BLm (S132). When the voltage holding part 210 holds the sum of the currents of the bit lines from pages k to n, the column adding part 220_0 to the column adding part 220_q calculate voltages equal to the voltages held in the voltage holding part 210. On the other hand, when the voltage holding part 210 holds the current of the bit line when each page is read, the column adding part 220_0 to the column adding part 220_q sequentially add the voltage held by the voltage holding part 210 each time each page is read.

Next, the row adding part 222 inputs the voltage added by the column adding part 220_0 to the column adding part 220_q, and adds up these input voltages (S140). In this way, the sum of the voltages corresponding to the current flowing in the bit line when reading is performed from k pages to n pages is calculated. Then, the sum of the voltages is converted into digital data of a plurality of bits through the A/D conversion part 230, and is written into the selected page of the selected block of the storage plane P1. Description related to writing will be provided later.

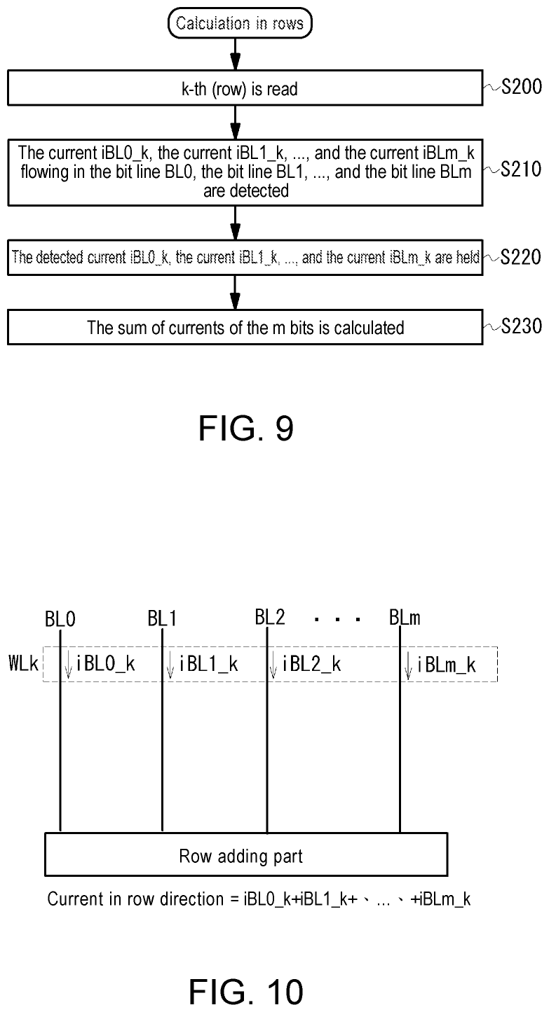

Among one of the embodiments, the controller 150 may perform calculations in the row direction through the calculation processing part 190 according to new instructions. FIG. 9 is a flow showing an example of the operation in the row direction, and FIG. 10 is a schematic diagram for explaining the operation in the row direction shown in FIG. 9.

When receiving instructions and addresses for performing operations in the row direction from the host-side system, the controller 150 starts reading the k-th page according to the instructions. When the k-th page (row) of the storage plane P0 is read (S200), as shown in FIG. 10, the current corresponding to the data of the selected memory cell flows from the bit line BL0 to the bit line BLm to the source line. The current iBL0, current iBL1, . . . , and current iBLm are detected by the bit line current detection part 200 (S210).

The voltage holding part 210 holds the voltage corresponding to the current of the bit line detected by the bit line current detection part 200 (S220), and then the row adding part 222 calculates the sum of the currents iBL0_k+iBL1_k . . . iBLm_k in the row direction of m bits (S230).

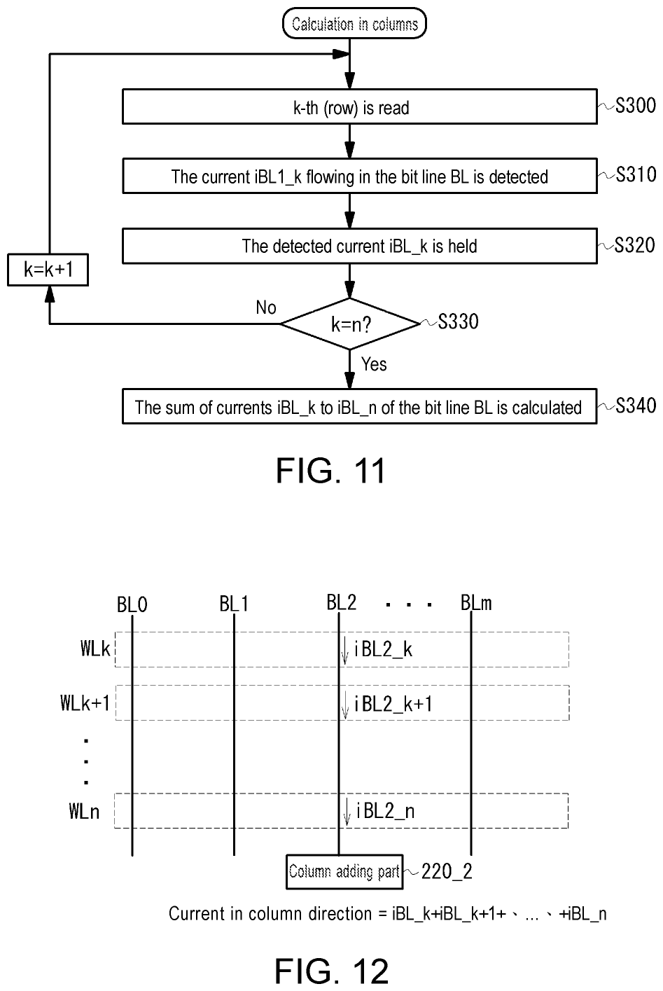

In another embodiment, the controller 150 may perform calculations in the column direction through the calculation processing part 190 according to new instructions. FIG. 11 is a flow showing an example of the operation in the column direction, and FIG. 12 is a schematic diagram for explaining the operation in the column direction shown in FIG. 11.

When receiving instructions and addresses for performing matrix operations from the host-side system, the controller 150 starts to continuously read multiple pages according to the instructions. When the k-th page (row) of the storage plane P0 is read (S300), for example, the current iBL2_k flowing in the bit line BL2 is detected by the bit line current detection part 200 (S310), and the voltage corresponding to the detected current iBL2 is held by the voltage holding part 210 (S320).

During the period of continuously reading the k-th page to the n-th page, the current flowing in the bit line BL2 when each page is read is detected, and the voltage corresponding to the currents is held in the voltage holding part 210 (S330). Next, the column adding part 220_2 calculates a voltage corresponding to the sum of the current iBL2_k to the current iBL2_n in the column direction (S340).

In the above embodiment, the current flowing in each bit line is detected by the bit line current detection part 200_0 to the bit line current detection part 200_q respectively. However, the above embodiment is an example, and the sum of the currents flowing in multiple bit lines may also be detected. Under the circumstances, with the multiple bit lines as one cell (unit), the bit line current detection part 200 detects the sum of the currents flowing in multiple bit lines of each unit. For example, when one cell includes 16 bit lines, the bit line current detection part 200 detects the sum of currents flowing in the 16 bit lines. For example, the bit line current detection part 200 detects the sum of the currents flowing in the shunt resistors connected to the 16 bit lines, and supplies the detected voltage to the voltage holding part 210. Detection of the sum of the currents flowing in the multiple bit lines read in the same row is equivalent to the addition process of the current flowing in the bit lines in the row direction explained in the previous embodiment (see FIG. 9, FIG. 10).

In addition, in another embodiment, multiple bit lines in units of cells may be commonly connected to the source line, and the bit line current detection part 200 detects the current flowing in the common source line in units of cells, that is, the sum of currents flowing in multiple bit lines in units of cells and flowing in a common source line in units of units, the sum of the currents is detected by the bit line current detection part 200.

In another embodiment, in the case of a structure such as a NOR type flash memory in which a read voltage is applied to a bit line from a voltage supply unit of a read circuit and the voltage or current of a source line is read, the bit line current detection part 200 may detect current supplied from the current supply part to the multiple bit lines (in units of cells). The voltage supply unit supplies a read voltage to each of multiple bit lines constituting the cell, and a current corresponding to the data stored in the memory cell flows from the bit lines toward the source line. The current supplied from the voltage supply part to the multiple bit lines constituting the cell is equal to the sum of the currents flowing from each bit line to the source line.

In this way, by using the bit line current detection part 200 to detect the sum of the currents flowing in the multiple bit lines constituting the cell, it is possible to reduce the number of circuits in the bit line current detection part 200, the voltage holding part 210 and the adding part 220, thereby reducing the space required for the circuits.

Next, an example of writing the result of a matrix operation into other blocks will be described. In an embodiment, the controller 150 writes the result of the matrix operation obtained during the reading of the storage plane P0 into the storage plane P1. However, the above embodiment is only an example, and the operation result may also be written into the same storage plane.

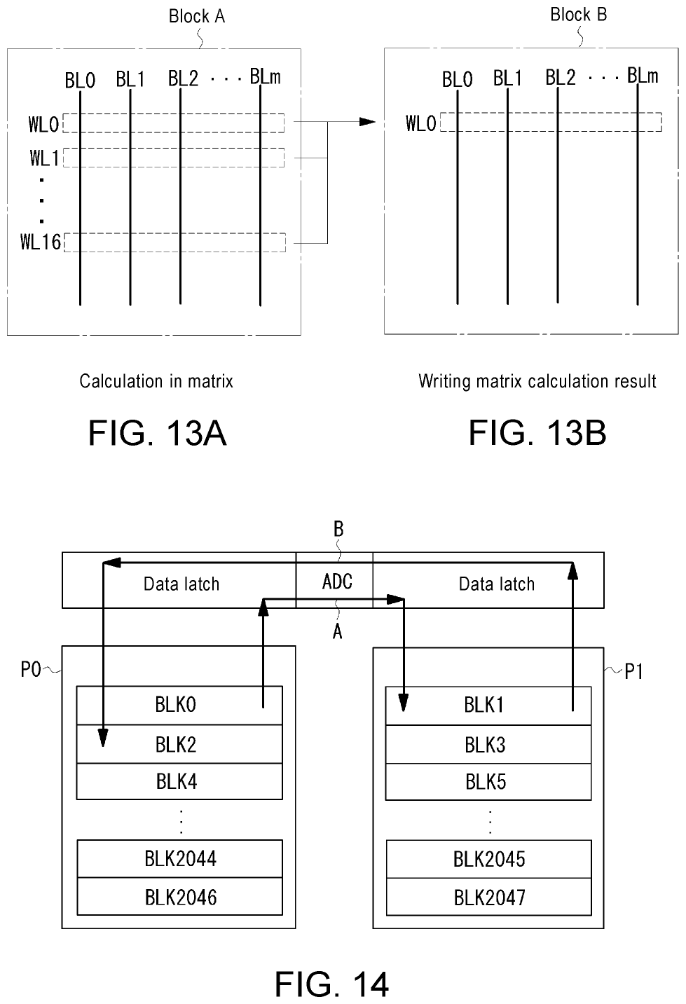

FIG. 13A shows the result of the matrix operation when reading the page of word line WL0 to the word line WL16 of block A. FIG. 13B shows an example in which the operation result is written to the selected page of the word line WL0 of the block B. Matrix operations reflect the data stored in the memory cell of 16 rows×m columns. Assume that the memory cell stores binary data, and the A/D conversion part 230 converts the result of the matrix operation into m-bit digital data, so the data of the memory cell of 16 rows×m columns is compressed to 1/16. That is, the resolution (number of bits) of the A/D conversion part 230 is determined by to what extent the result of the matrix operation is compressed.

The above example shows an example of compressing and writing the results of the matrix operation. For example, the operation results in the row direction shown in FIG. 9 and FIG. 10 may also be compressed and written to other blocks, or the operation results in the column direction shown in FIG. 11 and FIG. 12 may also be compressed and written to other blocks. Under the circumstances, the ratio of compression by the A/D conversion part 230 may also be determined.

FIG. 14 schematically shows an example of writing matrix operation results between storage planes. First, a matrix operation is performed in the reading operation of the block BLK0 of the storage plane P0, and the data obtained by compressing the operation result is written into the block BLK1 of the storage plane P1 (indicated by arrow A). Through the above processing, the result of the matrix operation performed by reading the storage plane P0 is accumulated in the block BLK1 of the storage plane P1.

When data is accumulated in the block BLK1 of the storage plane P1, a matrix operation is performed in the reading operation of the block BLK1, and the data obtained by compressing the operation result is written to the block BLK0 of the storage plane P0 (indicated by arrow B). By alternately switching between the storage plane P0 and the storage plane P1 for reading and writing, matrix operations on data stored in multiple memory cells may be implemented in the flash memory. In addition, since the operation processing may be read externally and output not from the flash memory, or matrix operations and writing of results thereof may be performed in internal processing of the flash memory when inputting operation processing results from outside and writing the operation processing results, matrix operations may be processed more efficiently and processing time may be shortened.

A flash memory with a matrix operation function as in this embodiment may be applied to neuromorphic devices in the same way as a crossbar array with a variable resistance type memory.

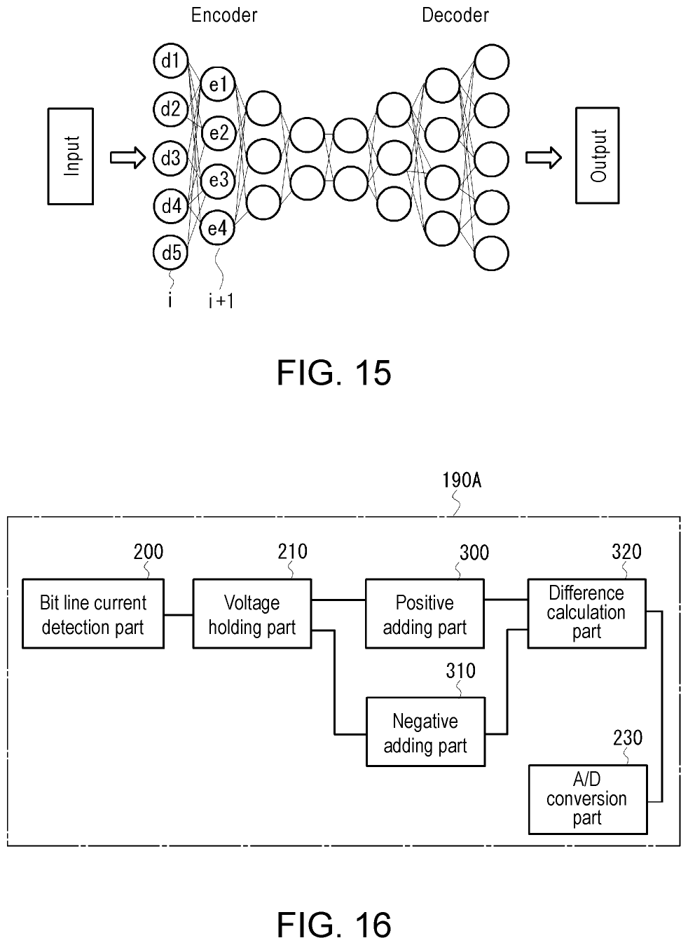

FIG. 15 shows an example of an auto-encoder using a neural network. The auto-encoder contains multiple encoder layers and multiple decoder layers between the input and the output. The weighting or coding of the encoder and decoder is adjusted through learning. The flash memory 100 performs processing at each layer of the encoder and decoder between input and output.

Each memory cell of the flash memory 100 stores weights or codes used for AI learning, and performs matrix operations on the data read from the i-th layer, for example, and writes the results thereof to the next i+1th layer. In the i+1th layer, matrix operation processing is performed on the data read from the i+1th layer, and the result thereof is written to the next i+2th layer, and the above process is repeated in sequence.

For example, the node d1, node d2, node d3, node d4, and node d5 of the i-th layer correspond to each page when being read, and the node e1 of the i+1-th layer corresponds to data obtained by performing A/D conversion on the sum of the current id1_WL1, the current id2_WL2, the current id3_WL3, the current id4_WL4, and the current id5_WL5 flowing in the bit line when reading the node d1, the node d2, the node d3, the node d4, and the node d5. The node e2 corresponds to data obtained by performing A/D conversion on the sum of the current id1_WL6, the current id2_WL7, the current id3_WL8, the current id4_WL9, and the current id5_WL10 flowing in the bit line when reading the node d1, the node d2, the node d3, the node d4, and the node d5. It should be noted here that the pages of the node d1 to the node d5 read when data is written to the node e1 are different from the pages of the node d1 to the node d5 read when data is written to the node e2. The A/D converted data is changed into WL voltage and transferred to the next hidden i+2 layer, and the number of nodes in the repeated hidden layer is read.

In this way, the flash memory 100 holds the learning data after compressing the features through matrix operation processing, and the external controller may use the learning data of the flash memory 100 to implement various processes (for example, image processing, prediction processing, natural language processing, etc.).

In this way, according to this embodiment, by configuring a flash memory with a matrix operation function, the flash memory may be used as a neuromorphic chip with an AI learning function.

Next, another embodiment of the present disclosure will be described. In matrix operations in AI learning, weighting coefficients or codes are increased or decreased in the positive or negative direction. That is, when the coupling strength of the synapse increases, the weight coefficient increases in the positive direction, and when the coupling strength decreases, the weight coefficient decreases in the negative direction.

In this embodiment, in order to realize the increase or decrease of the weight coefficient, it is assumed that half of the memory cells of m bits store positive data, and the remaining half of the memory cells store negative data. For example, the data of memory cells connected to even-numbered bit lines are assigned to positive weight coefficients, and the data of memory cells connected to odd-numbered bit lines are assigned to negative weight coefficients. When the coupling strength between synapses is strong, the data represented by the memory cells of the even-numbered bit lines becomes larger. When the coupling strength becomes low, the data represented by the memory cells of the odd-numbered bit lines become larger.

FIG. 16 is a block diagram showing the structure of the calculation processing part of this embodiment. The calculation processing part 190A of this embodiment includes a bit line current detection part 200, a voltage holding part 210, a positive adding part 300, a negative adding part 310, a difference calculation part 320, and an A/D conversion part 230. Among them, the bit line current detection part 200, the voltage holding part 210, and the A/D conversion part 230 are configured in the same manner as in the previous embodiment, and therefore the description thereof is omitted.

The positive adding part 300 adds up the sum of the currents flowing in the bit lines assigned with a positive weighting coefficient, such as the even-numbered bit lines, and the negative adding part 310 adds up the sum of the currents flowing in the bit lines assigned with a negative weighting coefficient, such as the odd-numbered bit lines. The difference calculation part 320 compares the addition result of the positive adding part 300 with the addition result of the negative adding part 310, calculates the difference, and supplies the difference to the A/D conversion part 230. The A/D conversion part 230 converts the difference into multiple bits of data.

It should be noted here that the difference calculation part 320 identifies which of the positive adding part 300 and the negative adding part 310 is larger. When the addition result of the positive adding part 300 is greater than the addition result of the negative adding part 310, the controller 150 performs control by writing the A/D converted data into the memory cell assigned with the positive weighting coefficient. When the addition result of the negative adding part 310 is greater than the addition result of the positive adding part 300, the control is performed in such a manner that the A/D converted data is written into the memory cell assigned with the negative weighting coefficient.

In this way, according to this embodiment, the difference between the sum of the currents flowing in the bit lines assigned with positive weight coefficients and the sum of the currents flowing in the bit lines assigned with negative weight coefficients is calculated. Therefore, it is possible to easily perform modulation based on the increase or decrease of the weight coefficient in AI learning.

In the above embodiment, a NAND type flash memory is exemplified, but the present disclosure may also be a NOR type flash memory. The NOR-type flash memory is not equipped with a circuit that reads one page of data like the NAND-type flash memory. However, for example, the NOR-type flash memory may sequentially switch the connection between the read circuit including the calculation processing part and the bit line to respectively detect the currents flowing in multiple bit lines.

Although the preferred embodiments of the present disclosure have been described in detail, the present disclosure is not limited to the specific embodiments, and various modifications and changes can be made within the scope of the spirit of the present disclosure described in the claims.

What is claimed is:

1. A calculating method, which is a calculating method of a semiconductor device comprising a memory cell array of a NOR type or NAND type, wherein in the calculating method,
a sum of currents flowing in a column direction of a plurality of bit lines when each row is read is calculated in a reading operation of a plurality of rows of the memory cell array.

2. The calculating method according to claim 1, further calculating the sum of the currents in the column direction and a sum of currents in a row direction of the plurality of bit lines.

3. The calculating method according to claim 2, wherein the calculating method calculates a sum of currents in a matrix direction corresponding to data stored in memory cells of a plurality of rows×a plurality of columns.

4. The calculating method according to claim 1, wherein the calculating method comprises performing an A/D conversion on the sum of the currents in the column direction or a sum of currents in a matrix direction to generate a plurality of bits of data.

5. The calculating method according to claim 4, further comprising writing the plurality of bits of data into memory cells of the memory cell array.

6. The calculating method according to claim 5, wherein the memory cell array comprises a first storage plane and a second storage plane,
in reading out the first storage plane, a sum of currents flowing in the bit line in a matrix direction is calculated, and the plurality of bits of data is written into the second storage plane.

7. The calculating method according to claim 1, wherein the calculating method calculates a sum of first currents flowing in a first group of bit lines in the column direction, and a sum of second currents flowing in a second group of bit lines in the column direction, as well as a difference between the sum of the first currents and the sum of the second currents.

8. The calculating method according to claim 7, wherein the sum of the first currents represents a positive coefficient and the sum of the second currents represents a negative coefficient.

9. A semiconductor device, comprising:
a memory cell array of a NOR type or NAND type, comprising a plurality of row lines, a plurality of bit lines, and a plurality of memory cells;
a reading part for reading out the memory cell array;
a writing part for writing the memory cell array; and
a calculating part for calculating a sum of currents flowing in a column direction of the plurality of bit lines when each row is read when the reading part performs reading of a plurality of rows.

10. The semiconductor device according to claim 9, wherein the calculating part further calculates the sum of the currents in the column direction and a sum of currents in a row direction of the plurality of bit lines.

11. The semiconductor device according to claim 10, wherein the calculating part calculates a sum of currents in a matrix direction corresponding to data stored in memory cells of a plurality of rows×a plurality of columns.

12. The semiconductor device according to claim 9, wherein the calculating part comprises an A/D conversion part performing an A/D conversion on the sum of the currents in the column direction or a sum of currents in a matrix direction to generate a plurality of bits of data.

13. The semiconductor device according to claim 12, wherein the writing part writes the plurality of bits of data into memory cells of the memory cell array.

14. The semiconductor device according to claim 13, wherein the memory cell array comprises a first storage plane and a second storage plane,
in reading out the first storage plane, the calculating part calculates a sum of currents flowing in the bit line in a matrix direction, and the writing part writes the plurality of bits of data into the second storage plane.

15. The semiconductor device according to claim 10, wherein the calculating part calculates a sum of first currents flowing in a first group of bit lines in the column direction and a sum of second currents flowing in a second group of bit lines in the column direction, as well as a difference between the sum of the first currents and the sum of the second currents.
